(19) United States
(12) Patent Application Publication
(10) Pub. No.: US 2009/0004812 A1
(43) Pub. Date: Jan. 1, 2009

(54) METHOD FOR PRODUCING SHALLOW TRENCH ISOLATION

(76) Inventor: Yung Chung LEE, Hsinchu County (TW)

Correspondence Address: BIRCH STEWART KOLASCH & BIRCH, PO BOX 747, FALLS CHURCH, VA, 22040-0747, US

(21) Appl. No.: 11/771,829

(22) Filed: Jun. 29, 2007

(51) Int. Cl. H01L 21/461

(52) U.S. Cl. 438/421; 257/E21.483

(57) ABSTRACT

The present invention provides a method for producing a shallow trench isolation, comprises: forming a plurality of first grooves on a silicon substrate with a mask etching method, wherein the silicon substrate comprises a silicon layer, an oxide layer and a first polysilicon layer; conducting oxidation process on an inner peripheral portion of the second grooves to form an insulting layer. The depth of the insulating layer on the periphery of the first polysilicon layer formed by the oxidation process is larger than the depths of the insulating layers that are formed on the silicon layer and on the oxidation layer through the oxidation process; filling high density plasma oxide layer into the second grooves to form a plurality of high density plasma oxide layer fillers; removing the first polysilicon layer by etching; covering the silicon substrate with a second polysilicon layer by deposition; and polishing the second polysilicon layer to form a plurality of self-aligned floating gate.

### TECHNICAL FIELD

The present invention provides a method for producing shallow trench isolation, and particularly to a method for producing shallow trench isolation preventing from over etching of self-aligned floating gate.

### BACKGROUND OF THE INVENTION

The shallow trench isolation (STI) technology has been developed as a necessary technical solution in the deep sub-micron semiconductor processing. As a result, the edge process of STI has become e one of the important topics, it must be able to eliminate the corner effect of the device, and maintain a complete gate oxide layer. Due to the decrease of thickness for the oxide layer, the above-mentioned topic becomes more important. Especially, the thinning effect of the oxide layer should be minimized in order to control the device. The conventional technique of preventing the oxide layer from thinning employed the corner rounding technique, but it still could not fully resolve the thinning problem of the oxide layer caused by the corner.

Thus, it is an objective of the present invention to teach a method for producing shallow trench isolation, in such to prevent the over etching of high density plasma oxide layer from occurring in the shallow trench isolation, and to reduce the thinning effect of the oxide layer.

### SUMMARY OF INVENTION

The inventor of the present invention has been in view of the defects of the conventional deep sub-micron semiconductor processing, and employed the manufacturing experience and technology accumulation on various deep sub-micron semiconductor processed, so as to focus on working out various solutions for the above-mentioned defects, and continuously research, experiment and improve to develop and design the method for producing shallow trench isolation according to the present invention, and expect to eliminate the defects occurred in the prior art. An object of the present invention is to provide a method of producing shallow trench isolation, so as to prevent the over etching of high density plasma oxide layer from occurring in the shallow trench isolation, and to reduce the thinning effect of the oxide layer.

To this end, the present invention discloses a method for producing shallow trench isolation, and the method includes:

(1) forming a plurality of first grooves on a silicon substrate with a mask etching method, in which the silicon substrate comprises a silicon layer, an oxide layer and a first polysilicon layer;

(2) conducting oxidation process on the periphery in the first grooves to form a plurality of second grooves, wherein an insulating layer is formed at the inner peripheral portion of the second grooves via the oxidation process. The depth of the insulating layer on the periphery of the first polysilicon layer formed by the oxidation process is larger than the depths of the insulating layers that are formed on the silicon layer and on the oxidation layer through the oxidation process;

(3) filling high density plasma oxide layer into the second grooves to form a plurality of high density plasma oxide layer fillers;

(4) removing the first polysilicon layer by etching;

(5) covering the silicon substrate with a second polysilicon layer by a deposition, and

(6) polishing the second polysilicon layer to form a plurality of self-aligned floating gates; and

when a plurality of second grooves are formed on the periphery of the first grooves via the oxidation process, the edges of the first polysilicon layer, the silicon layer and the oxide layer which are not etched in the Step (1) will be oxidized. Moreover, because the first polysilicon layer is more easily to be oxidized than the silicon layer and the oxide layer, the insulating layer formed on the first polysilicon layer will have a thicker layer during the oxidation process compared to the insulating layers formed on the silicon layer and the oxide layer. When the first polysilicon layer is removed through the etching process in the Step (4), it can prevent the high density plasma insulating layer from over etching in the shallow trench isolation, so as to reduce the thinning effect on the insulating layer.

### BRIEF DESCRIPTION OF DRAWINGS

FIG. 1 is a flow chart of a method for producing shallow trench isolation according to a preferred example of the present invention.

FIG. 2 is a cross-sectional flow diagram of a shallow trench isolation produced by the method according to the preferred example of the present invention.

FIG. 3A and FIG. 3B are the micrographic enlarged views, which exhibit the depth of the insulating layer formed in the oxidation process for the conventional shallow trench isolation and for the shallow trench isolation according to a preferred example of the present invention, respectively.

### DETAILED DESCRIPTION OF PREFERRED EMBODIMENTS

The present invention will be described in details with the following embodiments in conjunction with the attached figures for fully understanding the objects, features and effects of the present invention. The description is as follows:

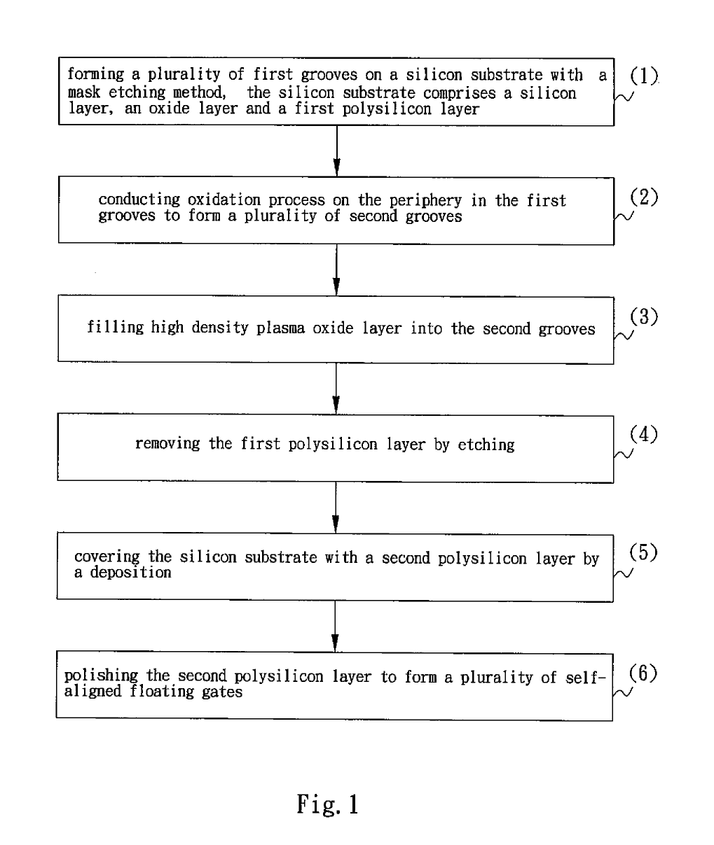

FIG. 1 is a flow chart of a method for producing shallow trench isolation according to a preferred example of the present invention. Please refer to FIG. 1, the shallow trench isolation method of the present invention comprises:

(1) forming a plurality of first grooves on a silicon substrate with a mask etching method, in which those first grooves are also called the shallow trench grooves, wherein the silicon substrate comprises a silicon layer (such as a silicon nitride layer, but not limited to), an oxide layer and a first polysilicon layer (such as a buffer polysilicon layer, but it does not limited to);

(2) conducting oxidation process on the periphery in the first grooves (such as the dry/wet oxidation process for the furnace, high temperature rapid thermal oxidation (RTO) process, or in-site steam generation oxidation (ISSO) process, but it does not limited to) to form a plurality of second grooves, wherein an insulating layer is formed at the inner peripheral portion of the second grooves via the oxidation process. The depth of the insulating layer on the periphery of the first polysilicon layer formed by the oxidation process is larger than the depths of the insulating layers that are formed on the silicon layer and on the oxidation layer through the oxidation process;

(3) filling a high density plasma oxide layer into the second grooves to form a plurality of high density plasma oxide layer fillers;

(4) removing the first polysilicon layer by etching;

(5) covering the silicon substrate with a second polysilicon layer (such as a floating polysilicon layer, but it does not limited to) by chemical vapor deposition method; and

(6) conducting the chemical mechanical polishing on the second polysilicon layer to form a plurality of self-aligned floating gates.

When a plurality of second grooves are formed on the periphery of the first grooves via the oxidation process, the edges of the first polysilicon layer, the silicon layer and the oxide layer which are not etched in Step (1) will be oxidized. It is due to that the first polysilicon layer is more easily to be oxidized than the silicon layer and the oxide layer, therefore, the insulating layer formed on the first polysilicon layer during the oxidation process will have a thicker layer compared to the insulating layers formed on the silicon layer and the oxide layer. Thus, when the first polysilicon layer is removed by the etching process in Step (4), it can prevent the high density plasma insulating layer from over etching in the shallow trench isolation, so as to reduce the thinning effect on the insulating layer.

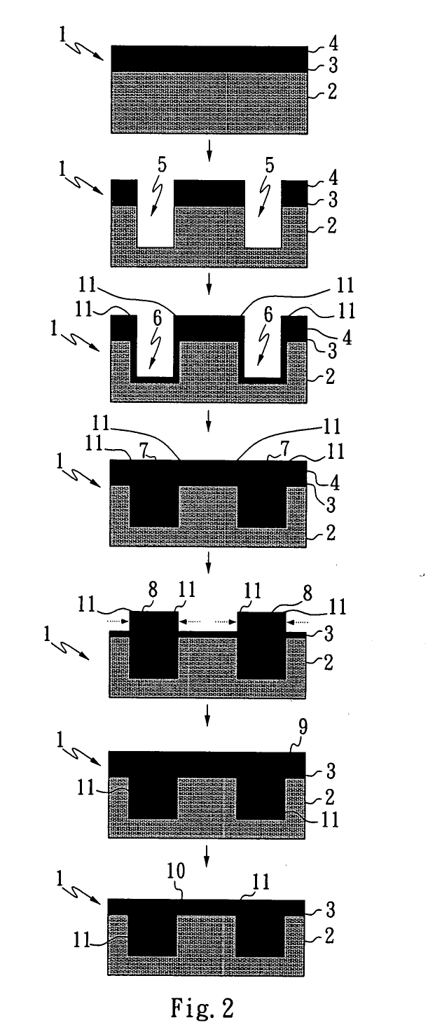

FIG. 2 is a cross-sectional flow diagram of the shallow trench isolation produced by a method according to a preferred example of the present invention. Please refer to FIG. 2, a plurality of first grooves 5 are formed firstly on a silicon substrate 1 with a mask etching method, wherein the silicon substrate 1 comprises a silicon layer 2 (such as a silicon nitride layer, but it does not limited to), an oxide layer 3, and a first polysilicon layer 4 (such as a buffer polysilicon layer, but not limited to). The method of the present invention further comprises the following processes: conducting the oxidation process on the periphery of the first grooves 5 (such as dry/wet oxidation process for the furnace, high temperature rapid thermal oxidation (RTO) process, or in-site steam generation oxidation (ISSG) process, but it does not limited to those processes) to form a plurality of second grooves 6, wherein an insulating layer 11 is formed at the inner portion of the periphery of the second grooves 6 via the oxidation process. The depth of the insulating layer 11 on the periphery of the first polysilicon layer 4 formed by the oxidation process is larger than the depths of the insulating layers 1 that are formed on the silicon layer 2 and on the oxidation layer 3 through the oxidation process;

;then, filling a high density plasma oxide layer 7 to these second grooves 6 to form a plurality of high density plasma oxide layer fillers 8; removing the first polysilicon layer 4 by etching; then, covering the silicon substrate I with a second polysilicon layer 9 (such as a floating polysilicon layer, but not limited to) by a chemical vapor deposition method; finally, employing the chemical mechanical polishing method to polish the second polysilicon layer 9 to form a plurality of self-aligned floating gate 10.

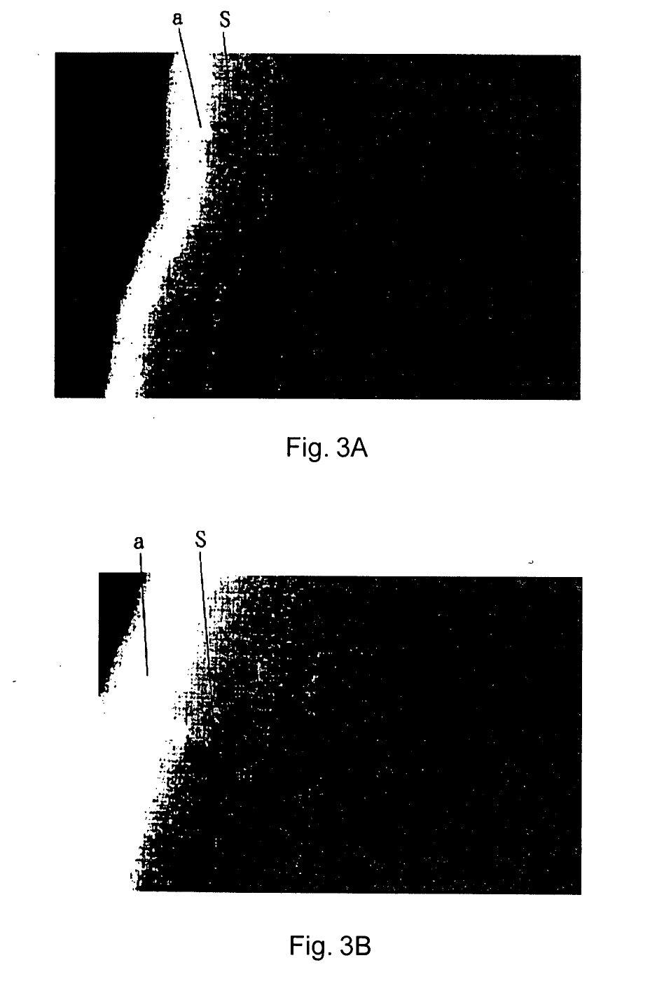

FIG. 3A is a micrographic enlarged view of the conventional shallow trench isolation, and FIG. 3B is a micrographic enlarged view of the shallow trench isolation according to a preferred example of the present invention, which exhibit the depth of the insulating layer formed in the oxidation process, respectively; wherein, the white area labeled with a-S is the insulating layer, whereas the black area on the right-hand side of the figure is the un-oxidized area. Since the first polysilicon layer according to the present invention is a buffer polysilicon layer, during employing the furnace of dry/wet oxidation process, the high temperature rapid thermal oxidation (RTO) process or the in-site steam generation (ISSG) oxidation process, the material utilized in the present invention will be easily oxidized to form a thicker insulating layer contrary to the material used for the first polysilicon layer in the conventional shallow trench isolation that is only composed of silicon nitride and silicon oxide, is not easily to be oxidized. Thus, as shown in FIG. 3A and FIG. 3B, the depth of the insulating layer for the shallow trench isolation according to the preferred example of the present invention is larger than the depth of the insulating layer of the conventional shallow trench isolation. Therefore, when the first polysilicon layer is removed by the etching process in Step (4), it will prevent the high density plasma oxide layer from over etching in the shallow trench isolation, so as to reduce the thinning effect on the insulating layer.

In which, the above-mentioned mask etching could be a dry etching process using chloro gas or fluoro gas, or a wet etching process using HF based on the requirements of actual situation.

From the above description, the present invention provides a method for producing shallow trench isolation in order to prevent the over etching of the high density plasma oxide layer from occurring in the shallow trench isolation, and to reduce the thinning effect of the oxide layer. Thus, the present invention is provided with the innovation and advancement from the view of patent, and with the industrial application on the market, which should be granted with the patent by the examiners.

What is claimed is:

1. A method for producing shallow trench isolation, comprising:
(1) forming a plurality of first grooves on a silicon substrate with a mask etching method, wherein the silicon substrate comprises a silicon layer, an oxide layer and a first polysilicon layer;
(2) conducting oxidation process on periphery of the first grooves to form a plurality of second grooves, wherein an insulating layer is formed at an inner peripheral portion of the second grooves via the oxidation process. The depth of the insulating layer on the periphery of the first polysilicon layer formed by the oxidation process is larger than the depths of the insulating layers that are formed on the silicon layer and on the oxidation layer through the oxidation process;
(3) filling high density plasma oxide layer into the second grooves to form a plurality of high density plasma oxide layer fillers;
(4) removing the first polysilicon layer by etching;
(5) covering the silicon substrate with a second polysilicon layer by a deposition; and
(6) polishing the second polysilicon layer to form a plurality of self-aligned floating gates.

2. A method of 1, wherein the silicon layer is a silicon nitride layer.

3. A method of claim 1, wherein the first polysilicon layer is a buffer polysilicon layer.

4. A method of claim 1, wherein the second polysilicon layer is a floating polysilicon layer.

5. A method of claim 1, wherein the etching method employs a dry etching process using chloro gas or fluoro gas.

6. A method of claim 1, wherein the etching method employs a wet etching process using HF.

7. A method of claim 1, wherein step (2) further comprises a dry/wet oxidation process for furnace on the periphery of the first grooves to form a plurality of second grooves.

8. A method of claim 1, wherein step (2) comprises conducting high temperature rapid thermal oxidation (RTO) process on the periphery of the first grooves to form a plurality of second grooves.

9. A method of claim 1, wherein step (2) comprises conducting in-site steam generation oxidation (ISSG) process on the periphery of the first grooves to form a plurality of second grooves.

10. A method of claim 1, wherein step (5) comprises covering the silicon substrate with a second polysilicon layer by a chemical vapor deposition method.

11. A method of claim 1, wherein step (6) comprises employing a chemical mechanical polishing method to polish the second polysilicon layer to form a plurality of self-aligned floating gates.
